(19) United States
(12) Patent Application Publication
(10) Pub. No.: US 2014/0293676 A1
(43) Pub. Date: Oct. 2, 2014

(54) PROGRAMMABLE IMPEDANCE MEMORY ELEMENTS AND CORRESPONDING METHODS

(71) Applicant: ADESTO TECHNOLOGIES CORPORATION, Sunnyvale, CA (US)

(72) Inventors: Wei Ti Lee, San Jose, CA (US); Janet Wang, Los Altos, CA (US); Chakravarthy Gopalan, Santa Clara, CA (US); Jeffrey Allan Shields, Sunnyvale, CA (US); Yi Ma, Santa Clara, CA (US); Kuei Chang Tsai, Cupertino, CA (US); John Sanchez, Palo Alto, CA (US); John Ross Jameson, Menlo Park, CA (US); Michael Van Buskirk, Saratoga, CA (US); Venkatesh P. Gopinath, Fremont, CA (US)

(21) Appl. No.: 14/195,787

(22) Filed: Mar. 3, 2014

Related U.S. Application Data
(60) Provisional application No. 61/771,930, filed on Mar. 3, 2013.

(51) Int. Cl. H01L 45/00; G11C 13/00

(52) U.S. Cl. CPC H01L 45/08; H01L 45/1658; G11C 13/0007
USPC 365/148; 257/4; 438/382

(57) ABSTRACT

A memory element programmable between different impedance states can include a first electrode; a switching layer formed in contact with the first electrode and including at least one metal oxide; and a buffer layer in contact with the switching layer. A buffer layer can include a first metal, tellurium, a third element, and a second metal distributed within the buffer layer. A second electrode can be in contact with the buffer layer.

This application claims the benefit of U.S. provisional patent application Ser. No. 61/771,930, filed on Mar. 3, 2013, the contents of which are incorporated by reference herein.

### TECHNICAL FIELD

The present disclosure relates generally to memory elements, and more particularly to memory elements programmable between two or more impedance states in response to the application of electric fields.

### BRIEF DESCRIPTION OF THE DRAWINGS

FIG. 1 is a side cross sectional view of a memory element according to an embodiment.

FIG. 2 is a side cross sectional view of a memory element according to another embodiment.

FIGS. 3A to 3C are side cross sectional views of memory elements according to further embodiments.

FIG. 4 is a graph showing a distribution of metal diffused through a buffer layer of memory element according to an embodiment.

FIGS. 5A and 5B are side cross sectional views of memory elements according to embodiments.

FIGS. 6A to 6D are side cross sectional views showing a method of making a memory element according to an embodiment.

FIGS. 7A to 7D are side cross sectional views showing a method of making a memory element according to another embodiment.

FIGS. 8A to 8F are side cross sectional views showing a method of making a memory element according to a further embodiment.

FIGS. 9A to 9D are blocks schematic diagrams of showing various modes of operation for reading a value from one or more elements according to embodiments.

FIG. 10 is a blocks schematic diagram showing a conventional method of programming an element.

FIGS. 11A and 11B are block schematic diagrams showing methods of programming an element according to embodiments.

### DETAILED DESCRIPTION

Embodiments disclosed herein programmable impedance elements programmable between different impedance values in order to store data. Such elements can include a metal oxide based switching layer on which can be formed a buffer layer. A buffer layer can include tellurium in combination with a number of other elements, including first metal, a third element, and a second metal. A second metal can be diffused through the buffer layer, including up to an interface with the metal oxide layer. The third element can reduce defects and/or help the buffer layer maintain an amorphous structure.

In very particular embodiments, the second metal can be a metal that can form an alloy with tellurium and/or reduce the metal oxide of the switching layer (i.e., free up oxygen from such a layer to create oxygen vacancies).

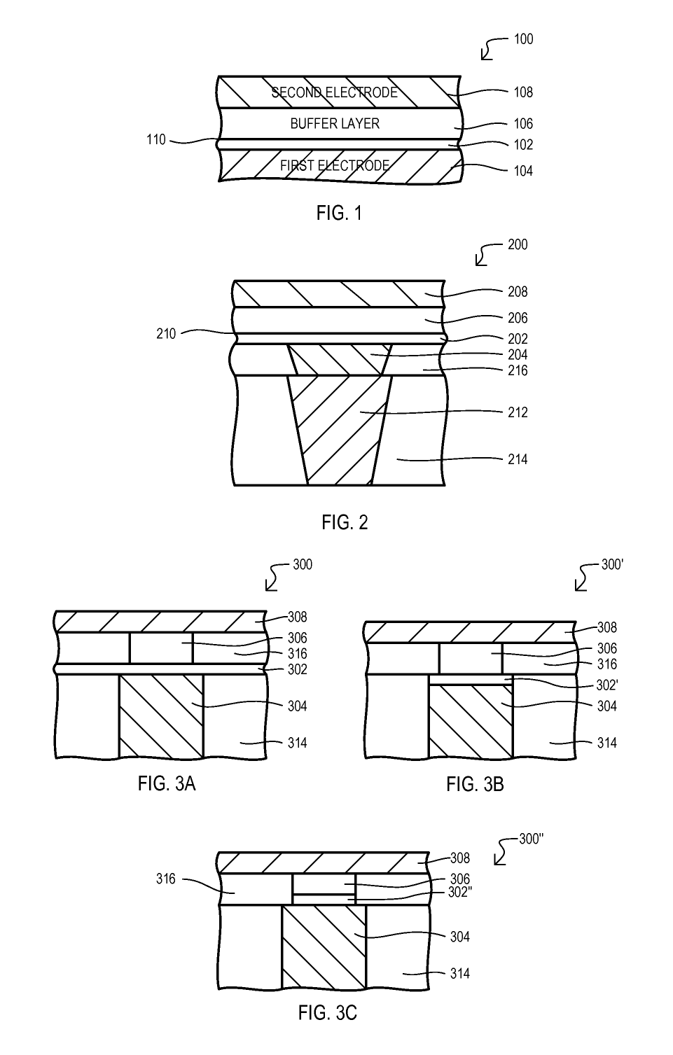

FIG. 1 is a side cross sectional view showing a memory element 100 according to one embodiment. A memory element 100 can include a switching layer 102 formed over a first electrode 104, and a buffer layer 106 formed on, and in contact with, the switching layer 102. A second electrode 108 can be formed over the buffer layer 106. By application of an electric field, a switching layer 102 can be programmed between two or more impedance states. In a particular embodiment, switching layer 102 can be programmed to change a resistance between first and second electrodes (104 and 108).

A switching layer 102 can include, or be formed entirely of, a metal oxide. Such a metal oxide can include, but is not limited to, gadolinium oxide (GdOx), hafnium oxide (HfOx), tantalum oxide (TaOx), aluminum oxide (AlOx), copper oxide (CuOx), a ruthenium oxide (RuOx), zirconium oxide (ZrOx) or silicon oxide (SiOx). Such metal oxides can include stoichiometric and non-stoichiometric forms.

In some embodiments, a switching layer 102 can include a metal oxide that is doped with another metal. Such an oxide doping metal can be a non-active metal. That is, such a metal is not ion conductible in the metal oxide. A metal for doping a switching layer metal oxide can be multivalent metal, such as nickel (Ni), tungsten (W), titanium (Ti), Ta or cesium (Ce), as but a few examples.

In some embodiments, a switching layer 102 can include more than one metal oxide. In some embodiments, switching layer 102 can be predominantly formed from one metal oxide, and then doped with a second metal oxide (or another metal that is subsequently oxidized to form the second metal oxide). In one very particular embodiment, a majority of a switching layer 102 can be formed from HfOx and/or GdOx that is doped with AlOx (or Al to form AlOx). Inclusion of AlOx may improve thermal and/or electrical stability of the switching layer 102. As but a few examples, a resulting switching layer 102 can have a higher reverse breakdown, improved erase performance (ability to be programmed to a high resistance state) and/or provide better erase (i.e., high resistance state) or program (low resistance state) distributions. Still further, when a switching layer 102 includes a rare earth oxide (e.g., GdOx), inclusion of AlOx can help suppress the hygroscopic nature of the rare earth oxide. When a switching layer 102 includes more than one metal oxide, the different metal oxides can be mixed together, can be in different layers, or a combination of both. A layered structure can also be formed by oxidizing first electrode 104 during the deposition of the switching layer 102.

In some embodiments, a switching layer 102 can include a metal oxide that is an oxide of the first electrode 104.

In some embodiments, a switching layer 102 can have a thickness from about 5 to 100 Å.

A buffer layer 106 can include a first metal, tellurium (Te), a third element, and a second metal distributed through the buffer layer 106. A first metal can be a metal that can ion conduct within the buffer layer 106. In some embodiments, such a metal can also ion conduct within the switch layer 102. In particular embodiments, a first metal can include Cu, Ag, or zinc (Zn).

In some embodiments, a first metal of a buffer layer 106 can be Cu, and a Cu—Te combination can have varying stoichiometry, including but not limited to CuTe₂, CuTe₆, and Cu₍₁₋ₓ₎Tex.

A third element of a buffer layer 106 can be an element that can reduce defects within the buffer layer 106 and/or tend to make the buffer layer 106 more amorphous (as opposed to more crystalline). In the latter case, absent the third element, a buffer layer 106 would be more crystalline. In particular embodiments, a third element can be any of germanium (Ge), Gd, Si, Sn or C. In a very particular embodiment, a buffer layer can include CuTe, and the third element can be Ge.

According to some embodiments, a first metal of a buffer layer 106 can be Cu, a third element can be Ge, and a Cu—Te—Ge combination can have varying stoichiometry, including but not limited to CuTeGe, CuTeGe₂, Cu₂TeGe, and CuTe₂Ge.

As noted above, a second metal can be distributed throughout the buffer layer 106 to an interface 110 of the buffer layer 106 and switching layer 102. In some embodiments, a second metal can selected based on its ability to diffuse through the buffer layer 106 to interface 110. In addition or alternatively, a second metal can be selected according to its ability to form an alloy with Te. In addition or alternatively, a second metal can be selected based on its ability to reduce the metal oxide of the switching layer 102. For example, a second metal can be selected by its ability to free up oxygen from the metal oxide and create oxygen vacancies in the switching layer 102. Still further, a second metal can also be selected based on its ability to make the buffer layer 106 more amorphous.

In particular embodiments, a second metal can be any of Ti, Zr, Hf, Ta, or Al. In a very particular embodiment, a buffer layer can include Cu, Te, and Ge, and the second metal can be Ti.

According to embodiments, the various components of a buffer layer 106 can be present in the following amounts: a first metal (e.g., Cu), 1-75 atomic percent; Te, 10-75 atomic percent; third element (e.g., Ge), 1-25 atomic percent; and second metal (Ti), 0.1 to 25 atomic percent.

In some embodiments, a buffer layer 106 can have a thickness from about 25 to 300 Å.

A first electrode 104 can be formed from a non-active metal, with respect to the switching layer 102. As such, for some types of memory elements, a first electrode 104 can be conceptualized as a “cathode” of the memory element (i.e., the memory element is a two terminal element, having an anode and a cathode). A first electrode 104 can be formed of any suitable patterned conductor of an integrated circuit device. According to embodiments, a first electrode 102 can be formed at a vertical level that is well above a substrate that contains transistors, or the like.

As noted above, in some embodiments a first electrode 104 can be formed from a metal of the metal oxide found in the switching layer 102.

In particular embodiments, a first electrode 104 can be formed from Ta, Zr, W, Ru, platinum (Pt), iridium (Ir), Hf, Gd, lanthanum (La), cobalt (Co), Ni, titanium (Ti) or Al. In addition or alternatively, a first electrode 104 can include a silicide or conductive nitrides, such as tantalum nitride (TaN) or titanium nitride (TiN), or a combination of any of the above.

A second electrode 108 can be formed over the buffer layer 106. In some embodiments, a second electrode 108 can be in contact with the buffer layer 106. A second electrode 108 can include the second metal present in the buffer layer 106. A second electrode 108 can be formed entirely of the second metal, or can include the second metal mixed with other elements. In addition, a second electrode 108 can include one or more other layers. As but one example, a second electrode 108 can include a layer of TiN formed over a layer of Ti.

In some embodiments, a second electrode 108 can be a diffusion source of the second metal with respect to the buffer layer 106. That is, the second metal can diffuse out from the second electrode 108 into the buffer layer 106. In such embodiments, a second electrode 108 can be in direct contact with the buffer layer 106 and the second metal can diffuse directly into the buffer layer 102. Alternatively, there can be an intermediary layer or material between the second electrode 108 and buffer layer 106 to control a rate at which the second metal can diffuse into the buffer layer 106.

In particular embodiments, a second electrode 108 can include any of Ti, Zr, Hf, Ta, or Al, and combinations thereof. In some embodiments, a second electrode can be a combination of Ti with Ag or Cu.

In some embodiments, a second electrode 108 can have a thickness from about 50 to 1000 Å.

Referring still to FIG. 1, while embodiments can be subject to the variations disclosed herein, and equivalent, in one specific embodiment, a memory element 100 can be a resistive random access (RRAM) element, programmable between two or more different resistance states by application of a voltage between an anode and a cathode. An anode can be an electrode, the direction from which, atoms can ion conduct through the buffer layer 106 and/or switching layer 102. In such a specific embodiment, a second electrode 108 can be titanium and form all, or part, of an anode. A buffer layer 106 can be a combination of Cu, Te and Ge with Ti diffused therein from the second electrode 108. A switching layer 102 can be HfOx, GdOx, or AlOx. A first electrode 104 can be a cathode.

In the above-noted specific embodiment, the inclusion of Ge within the CuTe buffer layer 106 is believed to make the buffer layer 106 more amorphous and/or maintain it in a more amorphous state. A more amorphous buffer layer 106 can have a greater resistivity than a more crystalline structure.

Also in the above-noted specific embodiment, Ti can diffuse through the buffer layer to the interface 110. Ti may remove oxygen from the metal oxide of the switching layer, creating oxygen vacancies therein. It is believed such action can result in a stronger setting/resetting of the element (i.e., setting the element to a relatively lower resistance and resetting it to a relatively higher resistance). In addition or alternatively, the inclusion of Ti in the buffer layer is also believed to increase and/or maintain an amorphous structure of the buffer layer 106.

FIG. 2 is a cross sectional view of a memory element 200 according to another embodiment. In a particular embodiment, a memory element 200 can be one very particular implementation of that shown in FIG. 1.

A memory element 200 can include first electrode 204, switching layer 202, buffer layer 206, and second electrode 208, and such items can be formed of the same materials and subject to the same variations as their counterparts described with reference to FIG. 1.

FIG. 2 differs from FIG. 1 in that a first electrode 204 can be formed on, and in electrical contact with, a contact or via structure or horizontal interconnect 212 formed within a first interlayer dielectric layer (ILD) 214. Further, a first electrode 204 can be formed in a second ILD 216. Accordingly, by vertical extension of contact/via structure 212, a memory element 200 can reside on a higher layer of an integrated circuit (i.e., well above a substrate).

In some embodiments, an integrated circuit device can include multiple second electrodes 204 and any of the switching layer 202, buffer layer 206 or second electrode 208 can extend over multiple second electrodes 204 (i.e., serve as a layer for multiple elements). It is understood that each such layer may correspond to a different number of memory elements or a same number of memory elements. For example, a switching layer 202/buffer layer 206 may be common to one set of memory elements, but a second electrode 208 may be common to a different set of memory elements. Alternatively, such layers may be common to a same set of memory elements.

In some embodiments, portions of a memory element can be formed in an opening (e.g., via) of one or more insulating layers. Examples such “in via” embodiments are shown in FIGS. 3A to 3C.

FIG. 3A is a cross sectional view of a memory element 300 according to another embodiment. In a particular embodiment, a memory element 300 can be one very particular implementation of that shown in FIG. 1. A memory element 300 can include a first electrode 304, switching layer 302, buffer layer 306, and second electrode 308, and such items can be formed of the same materials and subject to the same variations as their counterparts described with reference to FIG. 1.

FIG. 3A differs from FIG. 1 in that a first electrode 304 can be formed in a first ILD 314. In addition, a buffer layer 305 can be formed within an opening of a second ILD (e.g., it can be “in via”).

FIG. 3B is a cross sectional view of a memory element 300′ that can include the same items as FIG. 3A. FIG. 3B differs from FIG. 3A in that switching layer 302′ can be formed on a top portion of first electrode 304.

FIG. 3C is a cross sectional view of a memory element 300″ that can include the same items as FIG. 3A. FIG. 3C differs from FIG. 3A in that switching layer 302″ can be formed in a same opening as buffer layer 306.

As understood from embodiments disclosed herein, memory elements can include a stack that includes an ion buffer layer that contains Te and a second metal (e.g., Ti) diffused therein. In some cases, a second metal can be selected based on how it forms an alloy with Te and/or its reducing effect on metal oxide layer of a switching layer. The inclusion of the second metal may have the various advantages described herein.

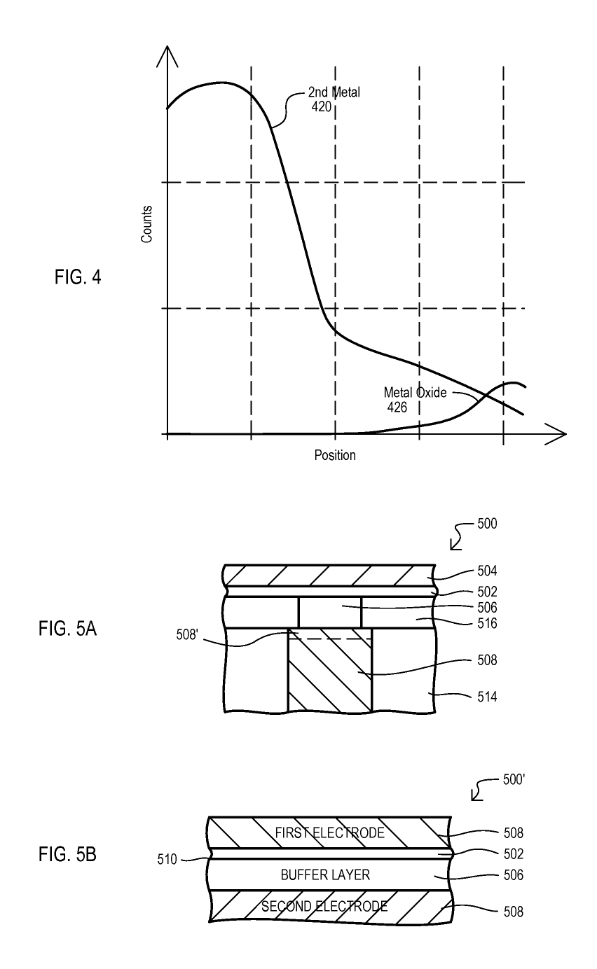

FIG. 4 is a graph showing how a second metal can diffuse into a buffer layer. The graph shows the presence of a second metal (curve 420) and a metal oxide of a switching layer (curve 426) by position (e.g., vertical position for the embodiments of FIGS. 1 and 2). As shown by the curve 420 as compared to the curve 426, a second metal can diffuse down to the buffer/switching layer interface.

While embodiments above have shown memory cell structures having a particular vertical order (vertical with respect to a substrate), such an arrangement should not be considered limiting. Alternate embodiments can include layers in the opposite vertical direction and/or in a lateral direction.

FIG. 5A is a side cross sectional view of a memory element 500 according to another embodiment, having a vertical arrangement different from that of FIGS. 1 to 3C. Accordingly, a memory element 500 can include a buffer layer 506 formed on a second electrode 508, a switching layer 502 formed on the buffer layer 506, and a first electrode 504 formed on a switching layer 502. Such items can be formed of the same materials and subject to the same variations as their counterparts described with reference to FIG. 1.

In FIG. 5A, a second electrode 508 can be formed in a first ILD 514. In particular embodiments, a second electrode 508 can include a second metal portion 508′ to enable a second metal to diffuse into a buffer layer 506 from the second electrode 508. A buffer layer 506 can be formed in an opening of second ILD 516.

FIG. 5B is a side cross sectional view of a memory element 500′ according to another embodiment having a vertical arrangement like that of FIGS. 1 to 3C. The items of FIG. 5B can be formed of the same materials and subject to the same variations as their counterparts described with reference to FIG. 1. FIG. 5B shows layers like those of FIG. 1, but in an opposite vertical order.

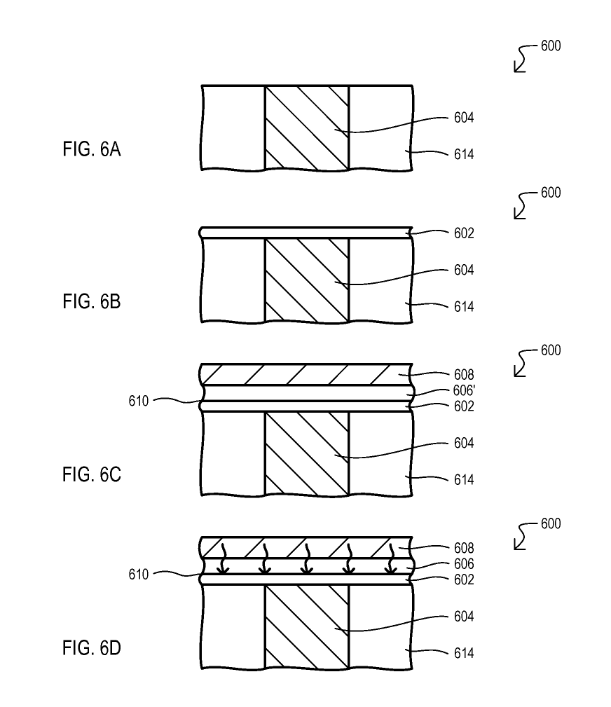

FIGS. 6A to 6D are a series of side cross sectional views showing a method of making a memory element 600 according to an embodiment. The various items and layers shown can be formed of the same materials and subject to the same variations as their counterparts described with reference to FIG. 1.

FIG. 6A shows the formation of a first electrode 604. In the embodiment shown, a first electrode 604 can be formed within a first ILD 614. In the example shown, a first electrode 604 can be planarized to be coplanar with the first ILD 614.

FIG. 6B shows the formation of a switching layer 602 over and in contact with first electrode 604. In the particular embodiment shown, a switching layer 602 can also be formed on first ILD 614.

FIG. 6C shows the formation of a buffer layer 606′ over and in contact with the switching layer 602, and the formation of a second electrode 608 over and in contact with the buffer layer 606′. According to some embodiments, buffer layer 606′ can include a first metal, tellurium and a third element. A second electrode 608 can include a second metal that is diffusible into the buffer layer 606′. In some embodiments, additional layers can be formed over the second electrode 608 to create a larger second electrode stack (e.g., TiN, TaN, etc.).

FIG. 6D shows the diffusion of a second metal into the buffer layer 606. In some embodiments, such an action can result in a buffer layer 606 that includes a first metal, tellurium, a third element, and the second metal from the second electrode 608. Diffusion of a second metal can be according to any methods suitable to the materials employed. In particular embodiments, one or more heat cycles can be used to diffuse Ti into a Cu—Te—Ge layer to create a Cu—Te—Ge—Ti buffer layer 606. It is noted that in some embodiments, following the formation of a second electrode 608 (and additional electrode layers if used) a memory element 600 can be subject to one or more heat cycles to diffuse second metal into the buffer layer 606. However, in alternate embodiments, expected heat cycles of a fabrication process steps that follow the formation of the memory element 600 can be used to accomplish all, or a portion of the diffusion of a second metal into the buffer layer 606.

It is noted that where appropriate, photodiffusion can be used to diffuse a second metal into a buffer layer.

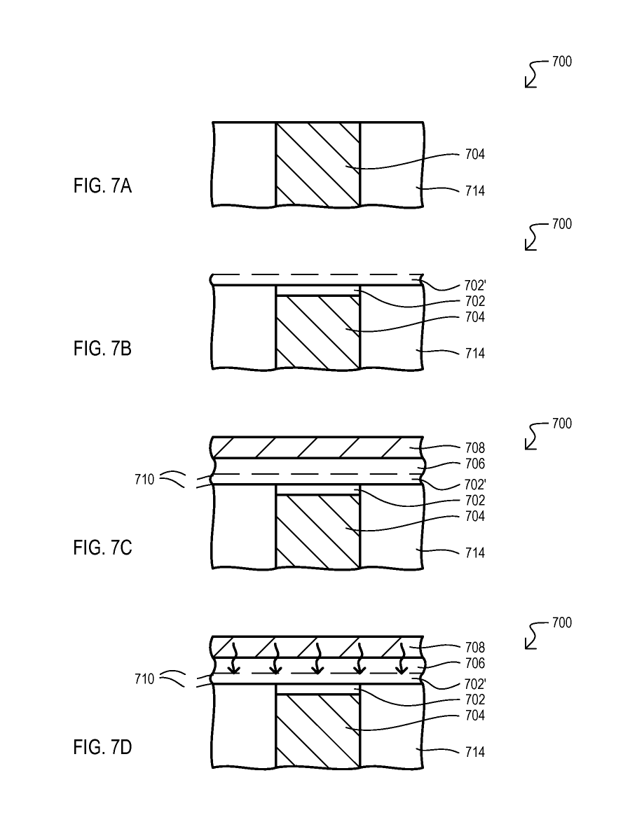

FIGS. 7A to 7D are a series of side cross sectional views showing a method of making a memory element 700 according to another embodiment. The various items and layers shown can be formed of the same materials and subject to the same variations as their counterparts described with reference to FIG. 1.

FIG. 7A shows the formation of a first electrode 704. In the embodiment shown, a first electrode 704 can be formed within a first ILD 714. However, it is understood that a first electrode can be a layer (i.e., like 104 in FIG. 1).

FIG. 7B shows the formation of a switching layer 702. In the particular embodiment shown, a switching layer 702 can be formed by applying a treatment to the first electrode 704. In one embodiment, a first electrode 704 can include one or more metals, and such a metal(s) can be oxidized to form a metal oxide of the switching layer 702. Optionally, one or more additional layers 702′ can be formed to complete a switching layer 702. As but one very particular example, an additional layer 702′ can be another metal oxide layer for a bi-layer structure.

FIGS. 7C and 7D can follow the same steps as described for FIGS. 6C and 6D. A position of interface 710 can vary according to whether or not additional layers 702′ are included.

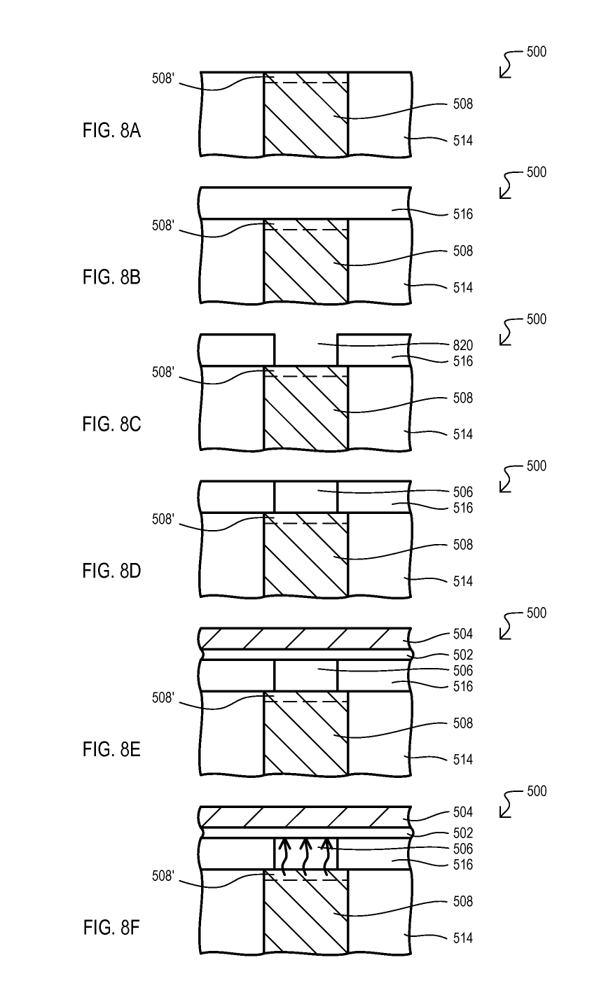

FIGS. 8A to 8E are a series of side cross sectional views showing a method of making a memory element like that of FIG. 5, according to an embodiment. The various items and layers shown can be formed of the same materials and subject to the same variations as their counterparts described with reference to FIG. 5.

FIG. 8A shows the formation of a second electrode 508. In the embodiment shown, a second electrode 508 can be formed within a first ILD 514. In some embodiments, second electrode 508 can include a second metal source 508′. In the embodiment shown, a second electrode 508 can be coplanar with first ILD 514.

FIG. 8B shows the formation of a second ILD 516 over the second electrode 508 and first ILD 514.

FIG. 8C shows the formation of an opening 820 in second ILD 516. An opening 820 can correspond to the size of a desired buffer layer.

FIG. 8D shows the formation of buffer layer 506 within an opening of second ILD 516. A planarization step can make the buffer layer 506 coplanar with second ILD.

FIG. 8E shows the formation of a switching layer 502 over and in contact with buffer layer 506, and the formation of a first electrode 504 over and in contact with the switching layer 502.

FIG. 8F shows the diffusion of a second metal into the buffer layer 506.

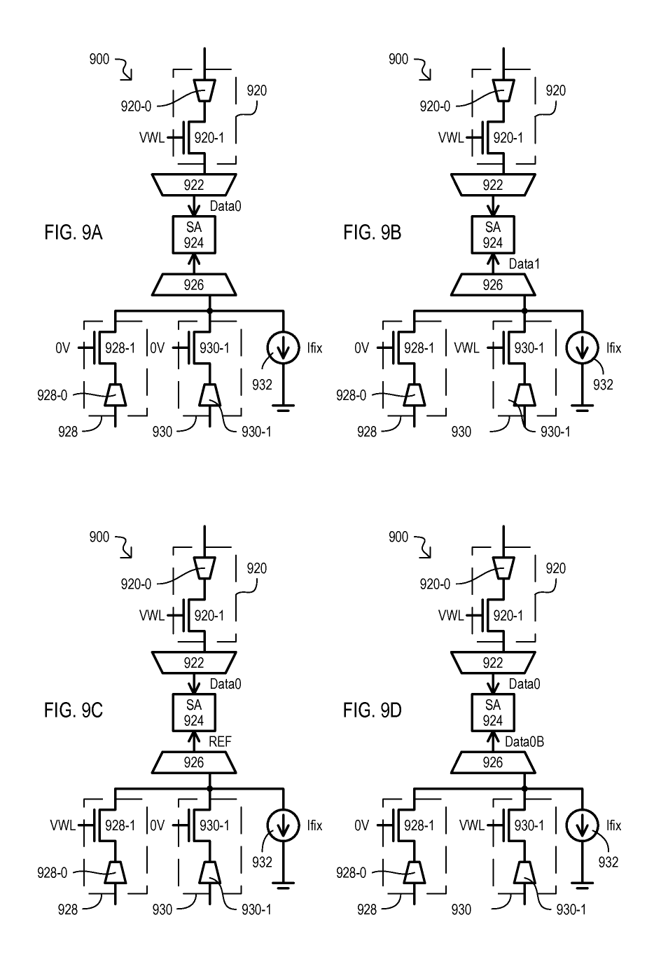

FIGS. 9A to 9D show a circuit and methods of reading data from a memory element according to various embodiments. A circuit 900 can include a first memory cell 920, first multiplexer (MUX) 922, sense amplifier (SA) 924, a second MUX 926, and a second memory cell 930. Optionally, a circuit 900 can also include a reference memory cell 928 and a current source 932.

FIG. 9A shows one mode of operation. In the operation of FIG. 9A, a data value stored by element 920-0 of memory cell 920 can be determined by SA 924. First MUX 922 can connect memory cell 930 to SA 924. Transistor 920-1 of memory cell 920 can be turned on by application of a voltage VWL to its gate, to connect element 920-0 to SA 924. Second MUX 926 can isolate SA 924 from memory cells 928, 930 and current source 932. SA 924 can sense a current through element 920 or a voltage across element 920 to sense the data value (Data0) stored by the memory element 920-0.

FIG. 9B shows another mode of operation. In the operation of FIG. 9B, a data value stored by memory cell 930 can be determined by SA 924. Sensing can occur as in the case of FIG. 9A, but with first MUX 922 isolating, and second MUX 926 connecting memory cell 930 to SA 924.

FIG. 9C shows a further mode of operation. In the operation of FIG. 9C, element 920-0 can be connected to SA 924 as in the case of FIG. 9A. However, in addition second MUX 926 can connect a reference value (REF) to another input of SA 924. Thus, SA 924 can determine a data value stored in element 920-0 by comparing it to the reference value VREF. In one embodiment, a transistor 928-1 within reference memory cell 928 can receive VWL, to connect a reference element 928-1 to SA 924. Optionally, at the same time, current source 932 can provide some fixed current. Alternatively, a reference memory cell 928 may not be used, and second MUX 926 can connect a reference current, provided by current source 932, to a second input of SA 924.

FIG. 9D shows another mode of operation. In the operation of FIG. 9D, a data value is stored by two memory cell with elements programmed to opposing states. In particular, memory element 920-0 of memory cell 920 can be programmed to one state (e.g., high resistance), while memory element 930-0 within memory cell 930 can be programmed to an opposite state (e.g., low resistance). In a sense operation, first MUX 922 connects memory element 920-0 to a first input of SA 924, while second MUX 926 connects memory element 930-0 to a second input of SA 924. Thus, one SA input receives a data value (Data0) while the other sense input receives a complementary data value (Data0B).

In some embodiments, a circuit can be programmable between the various modes shown. That is, by setting configuration values for the circuit 900, the circuit switch between two or more of the modes shown.

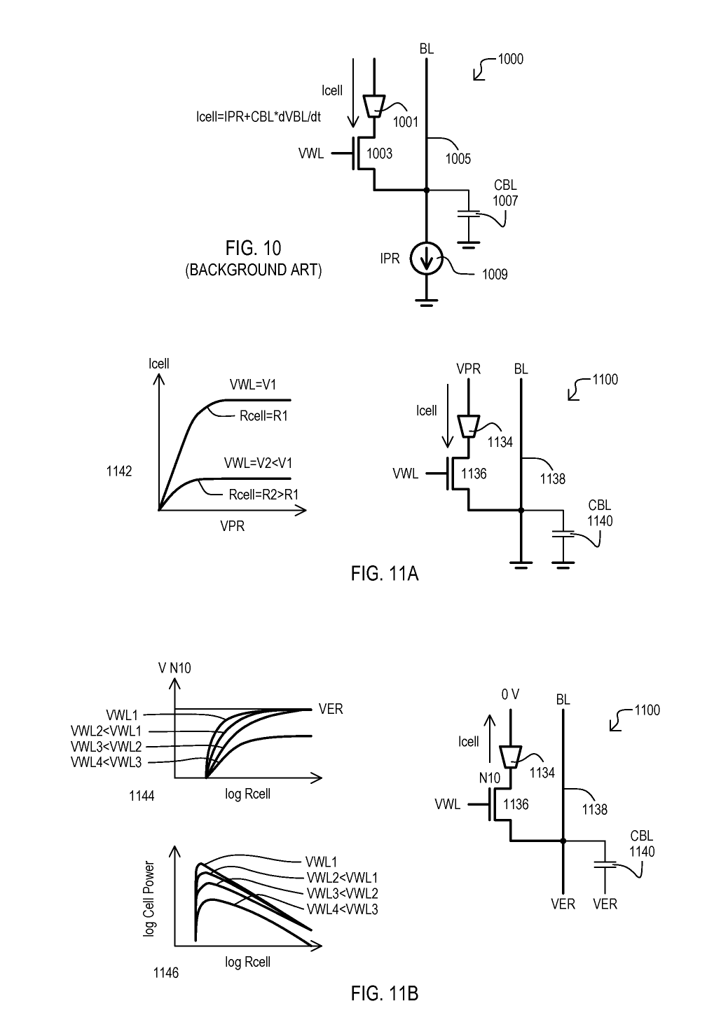

FIG. 10 shows a conventional programming operation. In a programming operation, an element 1001 can be connected to a bit line 1005 by a transistor 1003. A programming current source 1009 can be connected to bit line 1005 to draw a programming current IPR through element 1001 to program it. However, a bit line 1005 can have a capacitance (CBL 1007). Consequently, in the programming operation a programming current through element 1001 (Icell) will include a transient current CBL*dVBL/dt (where dVBL/dt is a change in bit line voltage over time).

FIG. 11A shows programming operation according to an embodiment in which a gate voltage to an access device can be used to reduce or eliminate the transient current noted in conjunction with FIG. 10.

FIG. 11A shows a circuit 1100 having a memory element 1134 connected to a bit line 1138 by an access device 1136. As shown by graph 1142, by lowering a gate voltage (VWL) of access device 1136, a current through element 1134 (Icell) can be reduced. In some embodiments, a gate voltage (VWL) can result in a current through Icell that is less than a saturation current of the transistor at the given program voltage VPR. In one embodiment, a programming voltage VPR can result in element 1134 being programmed to a low resistance state.

FIG. 11B shows a programming operation according to another embodiment in which a gate voltage to an access device can be reduced. FIG. 11B shows an arrangement like that of FIG. 11A, but voltage polarities (and thus Icell polarity) are opposite. As shown by graph 1144 reductions in word line voltage (VWL) can result in lower voltages or lower voltage rise rates across the element 1134. As shown by FIG. 11B, a lower gate voltage (VWL) can also result in lower power consumption by an element 1134.

It should be appreciated that reference throughout this description to “one embodiment” or “an embodiment” means that a particular feature, structure or characteristic described in connection with the embodiment is included in at least one embodiment of an invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

It is also understood that other embodiments of this invention may be practiced in the absence of an element/step not specifically disclosed herein.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claims require more features than are expressly recited in each claim. Rather, inventive aspects lie in less than all features of a single foregoing disclosed embodiment. Thus, the claims following the detailed description are hereby expressly incorporated into this detailed description, with each claim standing on its own as a separate embodiment of this invention.

What is claimed is:

1. A memory element programmable between different impedance states, comprising:
a first electrode;
a switching layer formed in contact with the first electrode and including at least one metal oxide;
a buffer layer in contact with the switching layer and comprising
a first metal,
tellurium,
a third element, and
a second metal distributed within the buffer layer; and
a second electrode in contact with the buffer layer.

2. The memory element of claim 1, wherein the switching layer metal oxide is selected from hafnium oxide, gadolinium oxide, tantalum oxide, copper oxide, aluminum oxide, ruthenium oxide, zirconium oxide, and silicon oxide.

3. The memory element of claim 1, wherein the switching layer comprises the metal oxide and at least one other metal.

4. The memory element of claim 3, wherein the other metal is selected from the group of: a metal that is not ion conductible in the switching layer and a multivalent metal.

5. The memory element of claim 1, wherein the buffer layer further includes the first metal being selected from copper, silver and zinc.

6. The memory element of claim 1, wherein the buffer layer further includes the third element being selected from germanium, gadolinium, silicon, tin and carbon.

7. The memory element of claim 1, wherein the third element amorphizes a structure of the buffer layer.

8. The memory element of claim 1, wherein the second metal can form an alloy with tellurium.

9. The memory element of claim 1, wherein the second metal reduces the at least one metal oxide layer.

10. The memory element of claim 1, wherein the buffer layer further includes the second metal being selected from titanium, hafnium, tantalum, aluminum, and zirconium.

11. The memory element of claim 1, wherein the second metal amorphizes a structure of the buffer layer.

12. The memory element of claim 1, wherein a vertical order of the layers and electrodes is, from top to bottom: the first electrode, the switching layer, the buffer layer, and the second electrode.

13. The memory element of claim 1, wherein at least a portion of the buffer layer is formed in an opening of a dielectric layer.

14. The memory element of claim 1, wherein:
within the buffer layer
the first metal is present in a range of about 1-75 atomic percent,
tellurium is present in a range of about 10-75 atomic percent,
the third element is present in a range of about 1-25 atomic percent, and
the second metal is present in a range of about 0.1 to 25 atomic percent.

15. A memory element programmable between different impedance states, comprising:
a first electrode;
a switching layer formed in contact with the first electrode and including at least one metal oxide;
a buffer layer in contact with the switching layer and comprising
a first metal that is ion conductible in the buffer layer,
tellurium,
a third element selected from the group of germanium, gadolinium, silicon, tin and carbon, and
titanium distributed within the buffer layer; and
a second electrode in contact with the buffer layer.

16. The memory element of claim 15 wherein the switching layer metal oxide is selected from hafnium oxide, gadolinium oxide, tantalum oxide, copper oxide, aluminum oxide, ruthenium oxide, zirconium oxide, and silicon oxide.

17. The memory element of claim 15, wherein the switching layer comprises the metal oxide and at least one other metal selected from the group of: a metal that is not ion conductible in the switching layer and a multivalent metal.

18. The memory element of claim 15, wherein the first metal is selected from copper, silver and zinc.

19. The memory element of claim 15, wherein
the first metal and third element are copper and germanium, respectively.

20. The memory element of claim 15, wherein
the second electrode comprises titanium.

21. A method of forming a memory element programmable between different impedance states, comprising:
forming a switching layer in contact with a first electrode that includes at least one metal oxide;
forming a buffer layer in contact with the switching layer that includes
a first metal that is ion conductible in the buffer layer,
tellurium,
a third element, and
forming a second electrode in contact with the buffer layer that includes a second metal; and
diffusing the second metal through the buffer layer to an interface of the buffer layer and switching layer.

22. The method of claim 21, wherein the switching layer metal oxide is selected from hafnium oxide, gadolinium oxide, tantalum oxide, copper oxide, aluminum oxide, ruthenium oxide, zirconium oxide, and silicon oxide.

23. The method of claim 21, wherein diffusing the second metal includes at least one heat treatment step.

24. The method of claim 23, wherein the at least one heat treatment step includes a heat cycle from a process step that follows the formation of the memory element layers.

25. The method of claim 21, wherein:
the second metal can form an alloy with tellurium.

26. The method of claim 21, wherein:
the second metal can reduce the at least one metal oxide.

27. The method of claim 21, wherein the buffer layer further includes the third element being selected from germanium, gadolinium, silicon, tin and carbon.

28. The method of claim 21, wherein:
the switching layer metal oxide is selected from aluminum oxide and gadolinium oxide;
the first metal of the buffer layer is selected from copper and silver; and
the third element of the buffer layer is selected from germanium and gadolinium; and
the second metal is titanium.

29. A method of sensing states of programmable impedance elements, comprising:
in a first mode
coupling a first element from a first group of the elements to a first input of a sense amplifier circuit, and
coupling a second element from a second group of the elements to a second input of the sense amplifier circuit; wherein
the first and second elements are programmed to different impedance states to represent one data value.

30. The method of claim 29, wherein:
in a second mode
coupling a selected element from the first group of the elements to the first input of the sense amplifier circuit, and
coupling a reference element to the second input of the sense amplifier circuit; wherein
the sense amplifier circuit is configured to compare an impedance between the selected element and the reference element to determine a data value stored by the selected element.

31. The method of claim 29, wherein:
in a second mode
coupling a selected element from the first group of the elements to the first input of the sense amplifier circuit, and
coupling a reference current to the second input of the sense amplifier circuit; wherein
the sense amplifier circuit is configured to compare a current through the selected element to the reference current to determine a data value stored by the selected element.

32. A method of setting a state of a programmable impedance element in a memory device, comprising:
applying a programming voltage between a first terminal of an element and a bit line; and
while the programming voltage is being applied, controlling a current flowing through an access device connected between a second terminal of the element and the bit line to by controlling the impedance of the access device via its gate voltage.

33. The method of claim 32, further including:
applying the programming voltage programs the element to a first resistance;
applying an erase voltage between the first terminal of the element and the bit line; and
while the erase voltage is being applied, controlling a current flowing through the access device to by controlling the impedance of the access device via its gate voltage; wherein
the eraes voltage has a polarity opposite to that of the programming voltage with respect to terminals of the element.
